(19) United States
(12) Patent Application Publication
(10) Pub. No.: US 2009/0166764 A1
(43) Pub. Date: Jul. 2, 2009

(54) TRANSISTOR AND FABRICATING METHOD THEREOF

(76) Inventor: Mun-Young Lee, Gyeyang-gu (KR)

Correspondence Address: SHERR & VAUGHN, PLLC, 620 HERNDON PARKWAY, SUITE 200, HERNDON, VA, 20170, US

(21) Appl. No.: 12/344,549

(22) Filed: Dec. 28, 2008

(30) Foreign Application Priority Data
Dec. 31, 2007 (KR) 10-2007-0141342

(51) Int. Cl. H01L 29/78; H01L 21/329

(52) U.S. Cl. 257/408; 438/230; 257/E29.256; 257/E21.351

(57) ABSTRACT

A transistor and fabricating method thereof includes sequentially forming a gate oxide layer and a poly gate over an active area of a semiconductor substrate, forming a drift region in the active area adjacent to the poly gate, and then forming a source/drain by simultaneously implanting impurity ions of various types into the drift region at a lower depth profile than that of the drift region.

The present application claims priority under 35 U.S.C. §119 to Korean Patent Application No. 10-2007-0141342 (filed on Dec. 31, 2007), which is hereby incorporated by reference in its entirety.

### BACKGROUND

In a circuit used for a driving LSI for a flat panel display, as LCD, PDP, OLED and the like, a vehicle LSI, an OA & peripheral device LSI and a motor driving LSI, a high-voltage device and a low-voltage device are integrated on and/or over a single chip. Such a circuit is called a high-voltage integrated circuit. In order to design the high-voltage integrated circuit, high-voltage MOS device model is necessary as well as low-voltage MOS device model.

FIGS. 1A to 1D are cross-sectional diagrams of a method of fabricating a NMOS transistor. Referring to FIG. 1A, after active areas (e.g., p-well 10) have been defined on and/or over a semiconductor substrate, a device isolation layer such as a shallow trench isolation 20 is formed for isolating active areas. After a gate oxide layer 30 has been formed and/or over the p-well 10, a poly gate 40 is formed on and/or over the gate oxide layer 30 by forming polysilicon on and/or over the gate oxide layer 30. N-drift region 50 is formed by performing lightly doped drain (LDD) ion implantation using the poly gate 40 as a mask. A spacer 60 is formed on both sidewalls of the poly gate 40.

Referring to FIGS. 1B and 1C, n+ contact regions (n+ source and drain) 70 are formed spaced apart a predetermined distance by implanting n+ ions into regions from the poly gate 40 using the photoresist pattern 65. Referring to FIG. 1D, silicide is formed on and/or over the poly gate 40 and the n+ contact regions 70.

However, since maximum electric field and ionization occur in the n+ contact regions 70, it is important to secure a distance from the n+ region spaced apart from the poly gate in order to enhance junction breakdown voltage characteristic enforcement, transistor leakage current characteristics and substrate current characteristics. Therefore, a pitch of transistor is increased.

### SUMMARY

Embodiments relate to a transistor and fabricating method thereof that decreases the distance between a poly gate and source/drain by reducing leakage current and electric field occurring in the source/drain junction region.

In accordance with embodiments, a method of fabricating a transistor may include at least one of the following: sequentially forming a gate oxide layer and a poly gate in an active area of a semiconductor substrate, forming a drift region in the active area adjacent to lateral sides of the poly gate, and forming a source and a drain by simultaneously implanting impurity ions in various types into the drift region.

In accordance with embodiments, a method may include at least one of the following: sequentially forming a gate oxide layer and a poly gate over an active area of a semiconductor substrate; and then forming a drift region in the active area adjacent at laterals sides of the poly gate; and then forming a source/drain by simultaneously implanting impurity ions of a first type and a second type into the drift region.

In accordance with embodiments, a transistor may include at least one of the following: a semiconductor substrate having defined therein an active area, a gate oxide layer and a poly gate sequentially stacked on and/or over the active area, a drift region in the active area adjacent to each of both sides of the poly gate, and a source and a drain in the drift region implanted with impurity ions in various types.

In accordance with embodiments, a device may include at least one of the following: a semiconductor substrate having an active area defined therein; a gate oxide layer formed over the semiconductor substrate in the active area; a poly gate formed over the gate oxide layer; a drift region formed in the semiconductor substrate in active area adjacent to the poly gate; and a source/drain formed in the drift region such that the source/drain are composed of ions of a first type and a second type.

In accordance with embodiments, leakage current and an electric field occurring in a junction between n+ source/drain and p-well by implanting impurities (e.g., P and As) into N-drift region. Therefore, embodiments are able to considerably reduce a size of transistor in a manner of decreasing a distance between a poly gate and n+ source/drain.

### DRAWINGS

FIGS. 1A to 1D illustrate a method of fabricating a NMOS transistor.

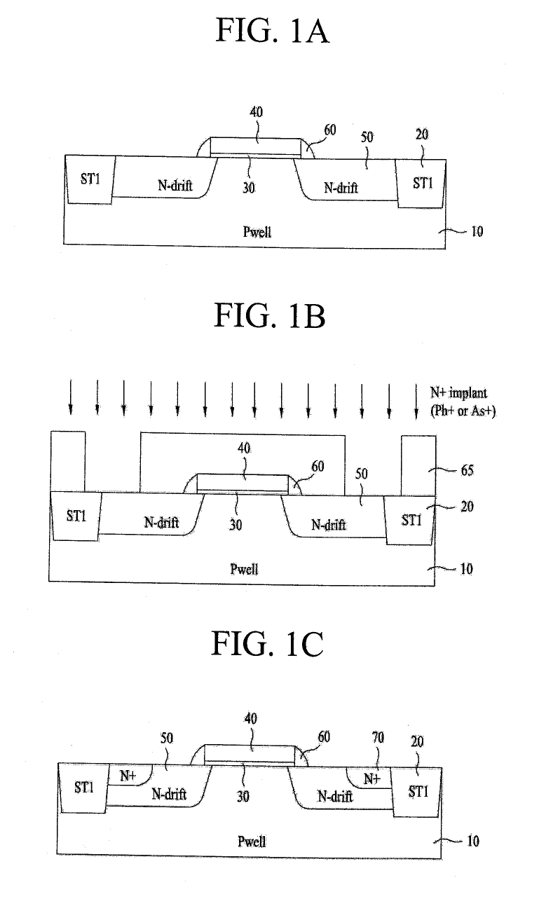

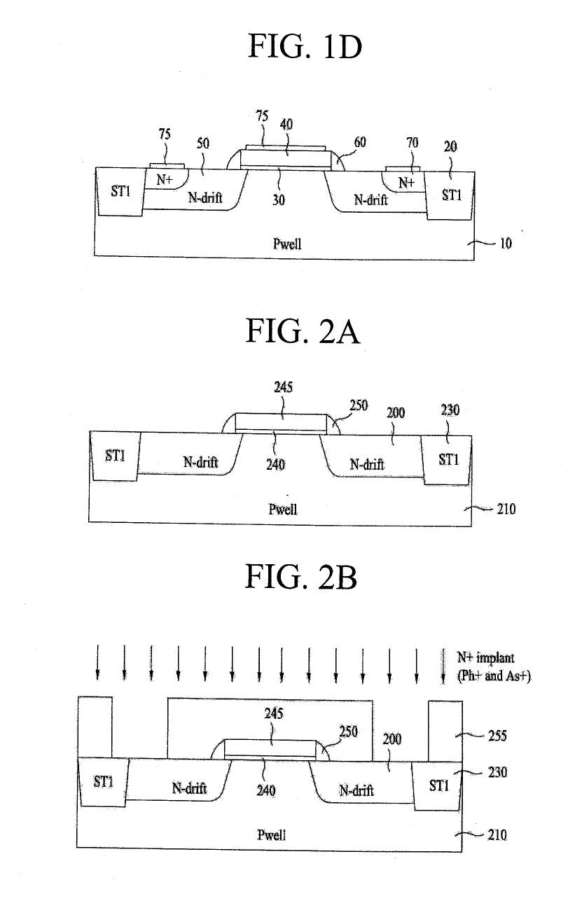

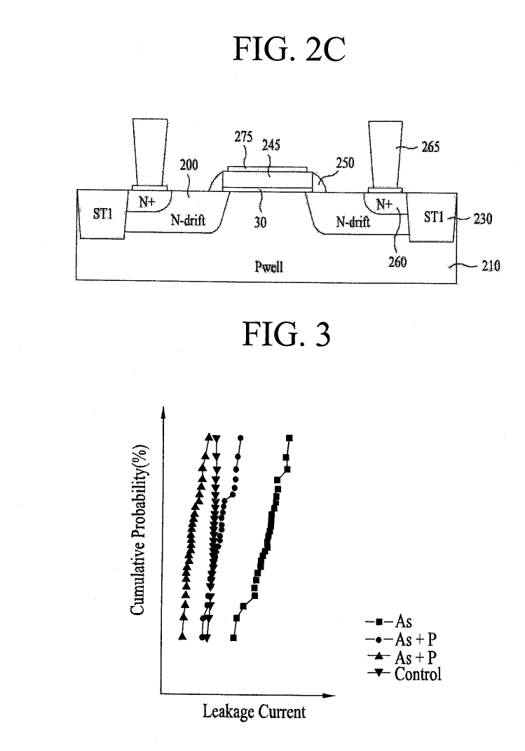

Example FIGS. 2A to 2C illustrate a method of fabricating an NMOS transistor in accordance with embodiments.

Example FIG. 3 is a graph illustrating the relation between leakage current and impurity ions injected for forming n+ source/drain.

### DESCRIPTION

Referring to example FIG. 2A, an active area 210 of a MOS transistor is defined in a semiconductor substrate and can include a p-well for NMOS transistor fabrication or an n-well for PMOS transistor fabrication. The active area becomes a part for forming a channel of the MOS transistor. In order to form the n-well, an epitaxial layer (epi-layer) is grown on and/or over the semiconductor substrate and is then lightly doped with a p-type impurity such as boron. After an initial oxide layer has been grown on and/or over the active area 210, a mask for patterning the active area is formed using photolithography. Ion implantation is then performed according to the mask using n-type impurities with high energy.

After a device isolation layer 230 for isolating a plurality of active areas from each other has been formed, a gate oxide layer 240 and a poly gate 245 are formed on and/or over the active area 210. In particular, after an oxide film has been grown on and/or over the active area 210, poly silicon is deposited on and/or over the oxide film. A first photoresist pattern for forming a poly gate is formed on and/or over the poly silicon by photolithography. The gate oxide layer 240 and the poly gate 245 are formed by selectively etching the poly silicon and the oxide film using the first photoresist pattern as an etch mask. An anisotropic plasma etch may be used as the etching process.

A drift region is formed at both lateral sides adjacent to the poly gate 245 by performing LDD ion implantation on the active area 210 using the poly gate 245 as a mask. In case of an NMOS transistor, N-type impurities such as one of potassium and arsenic can be implanted into the active area 210 via an open window of the etch mask. The region lightly doped with the n-type impurity is called an N-drift region 200. A depth profile of the N-type impurity implantation is lower than that of the n-well. In order to prevent punch-through attributed to a source/drain channel that becomes reduced due to the increased n+ source/drain injection, a spacer (i.e., sidewall spacer) 250 is formed on both sidewalls of the gate oxide layer 240 and the poly gate 245.

Referring to example FIG. 2B, a second photoresist pattern 255 is formed on and/or over the semiconductor substrate including the poly gate 245 by photolithography. The second photoresist pattern 255 can be formed on and/or over the device isolation layer 230, the poly gate 245 and the N-drift region 200. The second photoresist pattern 255 can be configured to have a mask window that opens a portion of the N-drift region 200 only.

Referring to example FIG. 2C, impurity ions of various types are simultaneously implanted into the N-drift region 200 via the mask window of the second photoresist pattern 255, thereby forming n+ source/drain 260. The impurity ions can include at least one of phosphorus ions and arsenic ions. The ion implantation may be performed using both the phosphorus ions and the arsenic ions. After the n+ source and drain 260 have been formed, the second photoresist pattern 255 is removed by a cleaning process. Subsequently, silicide 275 is formed by performing silicidation on and/or over the n+ source and drain 260. A contact 265 is then formed on the silicide 275.

Example FIG. 3 is a graph for a relation between leakage current and impurity ions injected for forming n+ source/drain. Referring to example FIG. 3, leakage current (first leakage current) generated from a junction between the n+ source/drain, which is formed by implanting either potassium or arsenic into the N-drift region 260, and the active area 210 is relatively greater than leakage current (second leakage current) generated from a junction between the n+ source/drain, which is formed by implanting both potassium and arsenic into the N-drift region 260 and the active area 210. Since the second leakage current is smaller than the first leakage current, if the n+ source/drain is formed by simultaneously implanting both P and As into the N-drift region 245, strength of an electric field generated from the n+ junction and a breakdown voltage of the n+ junction are reduced smaller than those of the case of implanting either P or AS into the N-drift region 245.

As mentioned in the foregoing description, the characteristic of the electric field generated from the n+ junction is affected by a spaced distance between the poly gate 245 and the n+ source/drain. For instance, if the spaced distance is too close, the strength of the electric field generated from the n+ junction gets bigger to increase the leakage current from the n+ junction. When a transistor is fabricated to have stable characteristics for electric field, breakdown voltage and impact ionization, if the n+ source/drain is formed by implanting both P and As into the N-drift region 265 in accordance with embodiments, the strength of the electric field generated from the n+ junction can be reduced. Therefore, it is able to bring an effect of reducing the spaced distance between the n+ source and drain. Eventually, the effect of reducing the distance between the n+ source and drain also reduces an overall pitch of transistor, i.e., the distance between the device isolation layers (STI) shown in example FIG. 2C, which is advantageous in implementing higher transistor integration. Moreover, the above characteristic enables silicide formation on n+ junction of an intermediate-voltage transistor, whereby breakdown voltage characteristic can be enhanced. Moreover, it is able to reduce a length of a poly gate of transistor as well.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
sequentially forming a gate oxide layer and a poly gate over an active area of a semiconductor substrate; and then
forming a drift region in the active area adjacent at laterals sides of the poly gate; and then
forming a source/drain by simultaneously implanting impurity ions of a first type and a second type into the drift region.

2. The method of claim 1, wherein forming the source/drain comprises:
forming a photoresist pattern over the semiconductor substrate exposing drift region; and then
simultaneously implanting the impurity ions of the first type and the second type into the drift region using the photoresist pattern as an ion implantation mask.

3. The method of claim 2, wherein the impurity ions of the first type and the second type are simultaneously implanted to have a depth profile lower than the drift region.

4. The method of claim 3, wherein the impurity ions of the first type comprises arsenic ions and the impurity ions of the second type comprises potassium ions.

5. The method of claim 1, wherein the impurity ions of the first type comprises arsenic ions and the impurity ions of the second type comprises potassium ions.

6. The method of claim 1, wherein the impurity ions of the first type comprises arsenic ions.

7. The method of claim 1, wherein the impurity ions of the second type comprises potassium ions.

8. The method of claim 1, wherein forming the drift region comprises implanting N-type impurities into the semiconductor substrate.

9. The method of claim 1, further comprising, after forming the source/drain, forming silicide over the source/drain and the polygate.

10. The method of claim 1, further comprising, after forming the silicide, forming a contact over the silicide formed over the source/drain.

11. The method of claim 1, further comprising forming a spacer on sidewalls of the gate oxide layer and the poly gate.

12. A device comprising:
a semiconductor substrate having an active area defined therein;
a gate oxide layer formed over the semiconductor substrate in the active area;
a poly gate formed over the gate oxide layer;
a drift region formed in the semiconductor substrate in active area adjacent to the poly gate; and
a source/drain formed in the drift region, wherein the source/drain are composed of ions of a first type and a second type.

13. The device of claim 12, wherein the active area comprises a p-well.

14. The device of claim 13, wherein the drift region comprises an n-channel.

15. The device of claim 12, wherein the impurity ions of the first type comprises arsenic ions and the impurity ions of the second type comprises potassium ions.

16. The device of claim 12, wherein the impurity ions of the first type comprises arsenic ions.

17. The device of claim 1, wherein the impurity ions of the second type comprises potassium ions.

18. The device of claim 12, wherein the depth profile of the source/drain is lower than the depth profile of the drift region.

19. The device of claim 12, further comprising:
a spacer formed at sidewalls of the gate oxide layer and the poly gate;
silicide formed over the source/drain and the polygate; and
a contact formed over the silicide formed over the source/drain.

20. The device of claim 12, wherein the device comprises a transistor.
